(19) United States
(12) Patent Application Publication
(10) Pub. No.: US 2009/0195931 A1
(43) Pub. Date: Aug. 6, 2009

(54) HEAD SLIDER AND METHOD OF MANUFACTURING HEAD SUSPENSION ASSEMBLY

(75) Inventors: Hikaru WATANABE, Kawasaki (JP); Toru WATANABE, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/331,969

(22) Filed: Dec. 10, 2008

(30) Foreign Application Priority Data
Feb. 5, 2008 (JP) 2008-025355

(51) Int. Cl. G11B 5/60; C23C 16/52

(52) U.S. Cl. 360/235.1; 427/8; 427/457

(57) ABSTRACT

A method of manufacturing a head suspension assembly for mounting a head slider on a suspension includes an irradiating light step, acquiring position information step and head slider mounting step. The irradiating light step is the step of irradiating light on a protective film and a marker at an incidence angle θ. The acquiring position information step is the step of acquiring position information of the marker by measuring reflected light from the protective film and that of the marker. The head slider mounting step is the step of mounting the head slider at a predetermined position of the suspension by using the difference of the intensity of reflected light from the protective film and that of the marker.

### CROSS-REFERENCE TO RELATED APPLICATION

This application is based upon and claims the benefit of priority of prior Japanese Patent Application No. 2008-25355, filed on Feb. 5, 2008, the entire contents of which are incorporated herein by reference.

### BACKGROUND

1. Field

An aspect of the invention is related to a method of manufacturing a head suspension assembly for mounting a head slider at a predetermined position of a suspension and a structure of the head slider.

2. Description of the Related Art

In a current hard disk drive, for example, a magnetic disk rotates at high speed. Air is drawn into a space between a head slider supported by a suspension and a magnetic disk, and the head slider is floated by pressurization thereof. A flying height will be 10 nm or less with increasing recording densities so that more stable flotation of the head slider is realized.

The suspension supporting the head slider has a protrusion, and an elastic force opposing buoyancy of the head slider is applied to the slider via the protrusion. On the other hand, buoyancy and the buoyancy center of the head slider are determined by an air bearing surface (hereinafter, referred to as the air bearing surface) pattern formed on the head slider.

Therefore, it is important to obtain stable flotation that a position relationship of the air bearing surface pattern of the head slider and the protrusion of the suspension. Currently, the mounting position to the suspension is generally fitted by visually recognizing an external shape of the head slider.

However, certain fluctuations in position relationship between the air bearing surface pattern of the head slider and the external shape of the head slider arise due to inaccuracy of polishing of the head slider. Therefore, even if the head slider is mounted at a predetermined position of the suspension based on the external shape, a flotation posture of the head slider may not be stable, leading to losses of flotation stability.

Japanese Laid-open Patent Publication 2005-149613 discloses a technique to fit the sticking position of the head slider by visually recognizing the external shape and air bearing surface pattern of the head slider. The air bearing surface pattern of the head slider can be mounted at a predetermined position of the suspension with precision.

However, unevenness of the air bearing surface pattern of the head slider is about 0.1 to 0.2 μm in portions with the least level differences. It is difficult to recognize the air bearing surface pattern with precision using the unevenness. If the air bearing surface pattern cannot be recognized with precision, the air bearing surface pattern cannot be mounted at a predetermined position of the suspension with precision.

### SUMMARY

Accordingly, it is an object of the embodiment to provide a method of manufacturing a head suspension assembly that mounts a head slider at a predetermined position of a suspension with high precision.

A method of manufacturing a head suspension assembly for mounting a head slider on a suspension includes an irradiating light step, an acquiring position information step and a head slider mounting step. The irradiating light step is the step of irradiating light on a protective film and a marker of the head slider at an incidence angle θ. The acquiring position information step is the step of acquiring position information of the marker of the head slider by measuring reflected light from the protective film and that of the marker. The head slider mounting step is the step of mounting the head slider at a predetermined position with respect to the suspension by using the difference of the intensity of reflected light from the protective film and that of the marker. The head slider has a device part for reading information from a medium or writing information to a medium, a body part to be a substrate for forming the device part, and a protective film and a marker formed on an air bearing surface opposite to the medium surface. When light is irradiated on the protective film and the marker, the intensity of reflected light from the protective film and that from the marker are different.

Additional objects and advantages of the embodiment will be set forth in part in the description which follows, and in part will be obvious from the description, or may be learned by practice of the invention. The object and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

The embodiments will be explained with reference to the accompanying drawings.

FIG. 1 shows a schematic diagram of an internal structure of a hard disk drive (HDD) according to the present invention;

FIGS. 2A and 2B show a side view of a head slider according to a first embodiment of the present invention;

FIGS. 3A and 3B show a side view of the head slider according to a second embodiment of the present invention;

FIGS. 4A and 4B show a side view of the head slider according to a third embodiment of the present invention;

FIG. 5 shows an explanatory view illustrating a reflected light on a marker surface of the head slider and a reflected light at an interface between the marker and a body part mutually being reinforced by multiple interference;

FIG. 6 shows a flow chart of a method of manufacturing a head suspension assembly according to the present invention; and

FIG. 7 shows an explanatory view illustrating a method of mounting the head slider on a tip side of a suspension.

### DETAILED DESCRIPTION OF THE PREFERRED EMBODIMENT

The embodiments will be described in detail below with reference to the accompanying drawings.

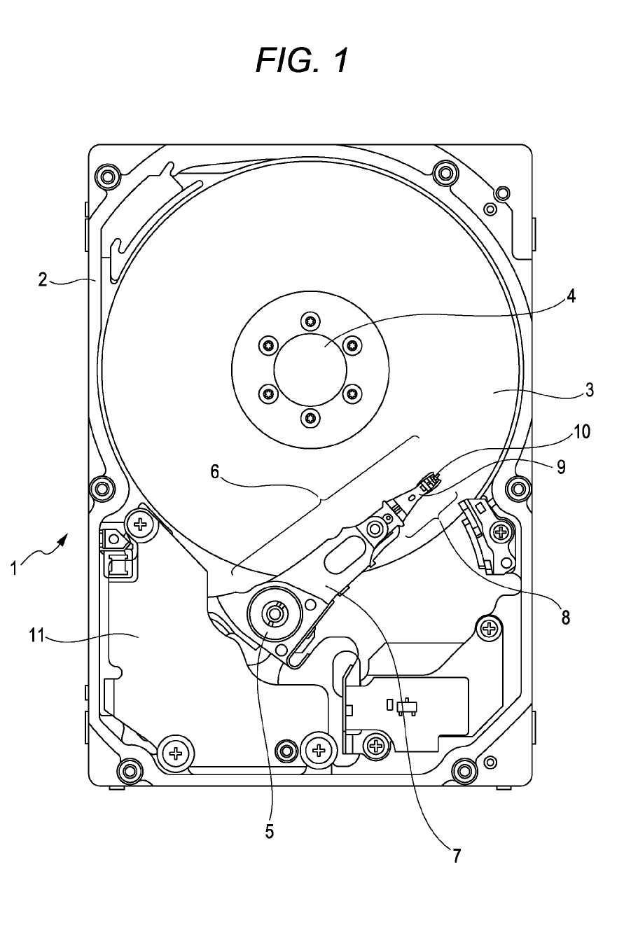

FIG. 1 schematically shows an internal structure of a recording disk driving device, that is, a hard disk drive 1 according to the embodiments of the present invention. The hard disk drive 1 has, for example, a box-shaped housing body 2 partitioning an internal space of a flat rectangular parallelepiped. One or more magnetic disks 3 as recording media are housed in the accommodating space. The magnetic disk 3 is fitted to a rotation axis of a spindle motor 4. The spindle motor 4 can rotate the magnetic disks 3 at high speed, for example, at 7200 rpm or 10000 rpm. A lid, that is, a cover (not shown) that seals the accommodating space between the housing body 2 and the cover is connected to the housing body 2.

A carriage 6 rolling around a pivot 5 extending in the vertical direction is further housed in the accommodating space. The carriage 6 includes an actuator arm 7 extending in the horizontal direction from the pivot 5 and made of a rigid body and a head suspension assembly 8 mounted to the tip of the actuator arm 7. In the head suspension assembly 8, a suspension 9 extends forward from the tip of the actuator arm 7. A head slider 10 is supported at the tip of the suspension 9. The head slider 10 includes, for example, a writing device (not shown) such as a thin-film magnetic head used for writing information to the magnetic disk 3 and a reading device (not shown) such as a tunnel junction magneto-resistance effect device (TMR) used for reading information from the magnetic disk 3.

A pressure acts on the head slider 10 toward the surface of the magnetic disk 3 from the suspension 9. Based on rotation of the magnetic disk 3, buoyancy acts on the head slider 10 by action of an air flow generated over the surface of the magnetic disk 3. The head slider 10 can continue to float with relatively high rigidity during rotation of the magnetic disk 3 by achieving a balance between the pressure of the suspension 9 and buoyancy.

If the carriage 6 rolls around the pivot 5 while the head slider 10 floats, the head slider 10 can cross the surface of the magnetic disk 3 in the radial direction. Based on such movement, the head slider 10 is positioned at a desired recording track on the magnetic disk 3. At this point, rolling of the carriage 6 may be realized through movement of a driving source 11 such as a voice coil motor (VCM). When a plurality of magnetic disks 3 is embedded in the housing body 2, the two actuator arms 7, that is, the two head suspension assemblies 8, are arranged between the adjacent magnetic disks 3.

[Structure of the Head Slider]

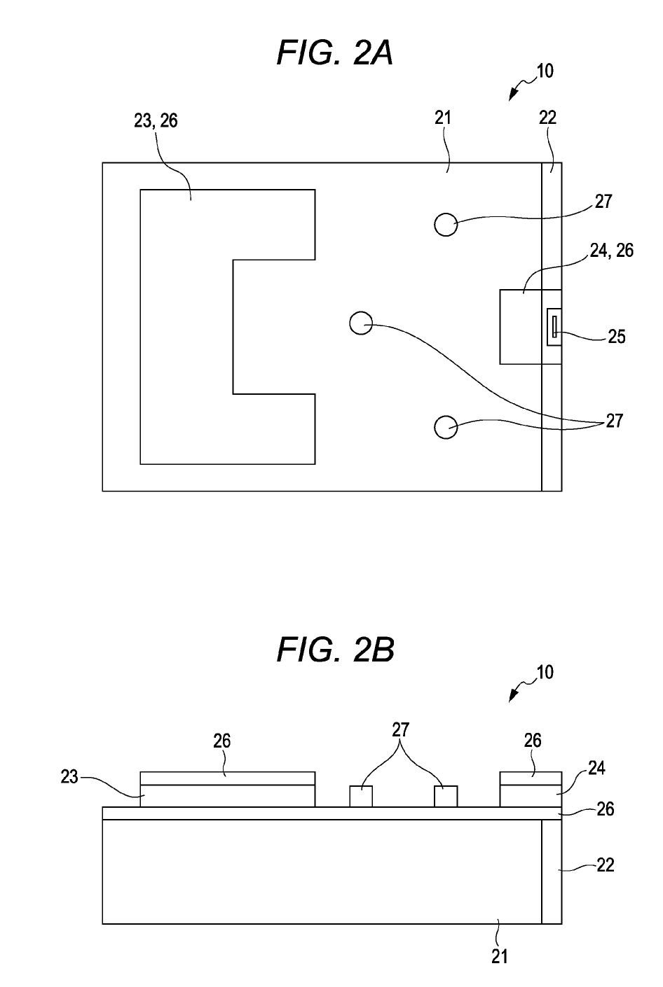

FIG. 2A and FIG. 2B show side views of the head slider 10 in the first embodiment of the present invention. FIG. 2A shows a side view when the head slider 10 is viewed from the air bearing surface side. FIG. 2B shows a side view when FIG. 2A is viewed from below. The head slider 10 includes a body part 21 made mainly of Al₂O₃—TiC and a device formation part 22 made of an insulating layer (for example, Al₂O₃). An air bearing surface pattern including a leading end side pad 23 and a trailing end side pad 24 is formed on the air bearing surface where the head slider 10 faces the magnetic disk during operation. An air flow taken in from the leading end side hits against the leading end side pad 23 to generate buoyancy.

The trailing end side pad 24 includes a device part 25, which is, in the example, provided in the central part of the head slider 10 in the width direction, but may also be provided at an end in the width direction. The air bearing surface pattern may also be constructed so that a force (negative pressure) that brings the head slider 10 closer to the medium is generated and thus, various shapes may be formed as needed. A protective film 26 made of DLC (diamond-like carbon) is formed all over the air bearing surface of the body part 21, the leading end side pad 23, and the trailing end side pad 24. Here, markers 27 used for position recognition are thicker than the protective film 26 in portions other than the markers 27, and is formed from material and with the thickness so that reflected light undergoes multiple interference under different conditions in portions other than the markers 27. With the three markers 27 in this embodiment, position recognition precision is improved with an increasing number of markers, but the number of markers may be one.

The markers 27 are formed, for example, by forming the protective film 26 to a predetermined thickness all over the air bearing surface of the head slider 10, forming a resist pattern so that the protective film 26 is exposed only in portions of the markers 27, and laminating a material that is the same as that of the protective film or different from that only in portions of the markers 27.

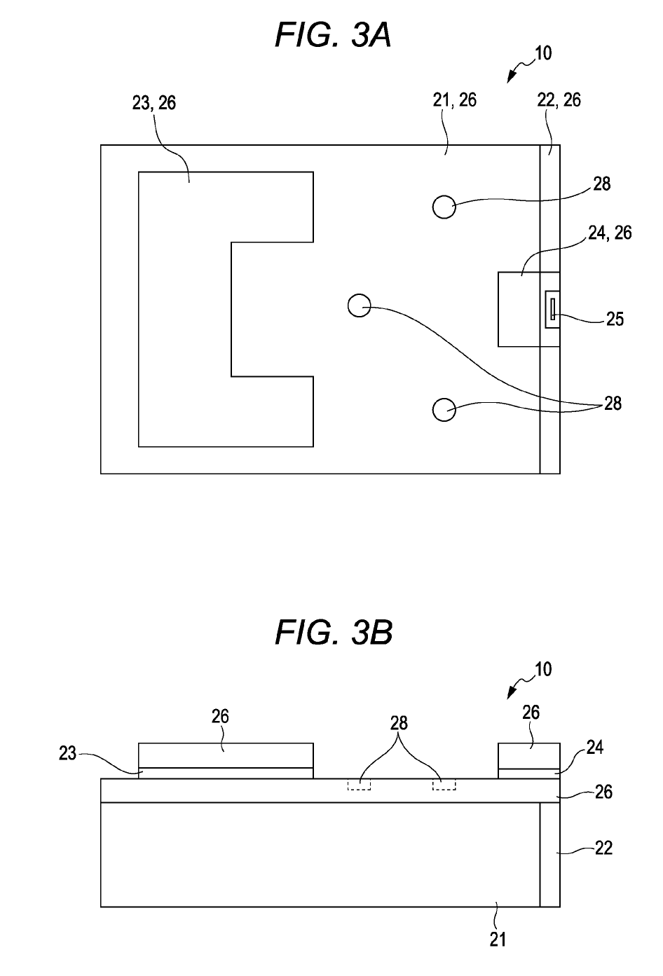

FIG. 3A and FIG. 3B show views of the head slider 10 in the second embodiment of the present invention. FIG. 3A shows a view when the head slider 10 is viewed from the air bearing surface side. FIG. 3B shows a side view when FIG. 3A is viewed from below. The same components are shown with the same reference numerals as those in the first embodiment. The second embodiment is the same as the first embodiment in that the head slider 10 is formed from the body part 21 and the device formation part 22 and an air bearing surface pattern including the leading end side pad 23 and the trailing end side pad 24 is formed on the air bearing surface. However, markers 28 used for position recognition are different from the first embodiment in that the markers 28 thinner than the protective film 26 in portions other than the markers 28, and are formed from material and with the thickness so that reflected light undergoes multiple interference under different conditions in portions other than the markers 28.

The markers 28 are formed, for example, by forming the protective film 26 to a predetermined thickness all over the air bearing surface of the head slider 10, forming a resist pattern so that the protective film 26 is exposed only in portions of the markers 28, and etching the protective film 26 in portions of the markers 28 to make the protective film in portions of the markers 28 thinner. Further, a different material may be laminated to form the markers 28.

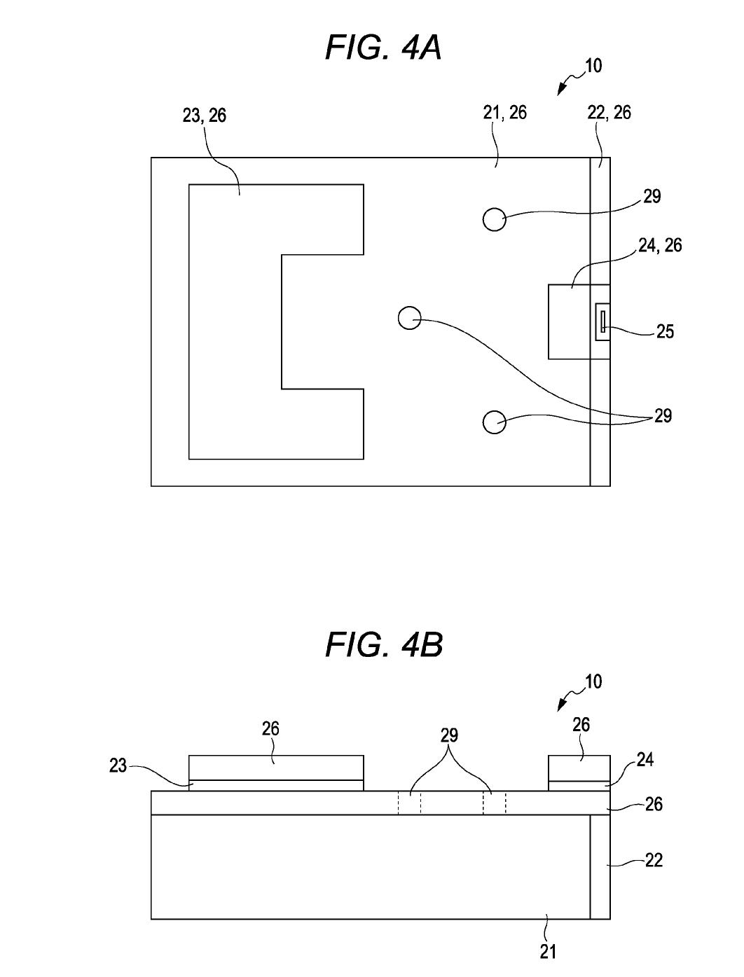

FIG. 4A and FIG. 4B show side views of the head slider in the third embodiment of the present invention. FIG. 4A shows a side view when the head slider 10 is viewed from the air bearing surface side. FIG. 4B shows a side view when FIG. 4A is viewed from below. The same components are shown with the same reference numerals as those in the first embodiment. The third embodiment is the same as the first embodiment and the second embodiment in that the head slider 10 is formed from the body part 21 and the device formation part 22 and an air bearing surface pattern including the leading end side pad 23 and the trailing end side pad 24 is formed on the air bearing surface. However, markers 29 used for position recognition are different from the first embodiment in that the markers 29 have the same thickness as the protective film 26 in portions other than the markers 29, and are formed from material so that reflected light undergoes multiple interference under different conditions than those in portions other than the markers 29.

The markers 29 are formed, for example, by forming the protective film 26 to a predetermined thickness all over the air bearing surface of the head slider 10, forming a resist pattern so that the protective film 26 is exposed only in portions of the markers 29, etching the protective film 26 in portions of the markers 29 to make the protective film in portions of the markers 29 thinner, and further laminating a different material.

In the first embodiment to the third embodiment, as described above, markers are constituted by a single material or two materials. However, the markers may be constituted by three or more different materials if the markers are designed so that reflected light from the markers are stronger or weaker than that from portions other than the markers due to multiple interference.

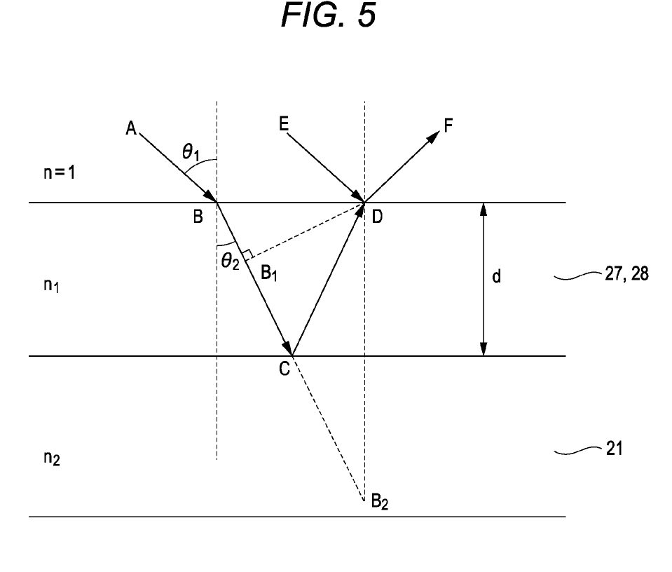

FIG. 5 shows an explanatory view illustrating that reflected light on a markers 27/28 surface of the head slider 10 and reflected light at an interface between the markers 27/28 and a body part 21 mutually are reinforced by multiple interference. If the index of refraction of the protective film 26 is n₁ and that of the body part 21 is n₂, the thickness d of the markers 27/28 causes multiple interference if a relationship of (1) is satisfied when light of a wavelength (λ) is irradiated at an incidence angle (θ) with respect to a direction perpendicular to the air bearing surface, and n₁>n₂,

$$λ = \frac{4 d}{2 m - 1} \times \sqrt{{n}_{1}^{2} - {sin}^{2} ϑ} ( m \text{:} natural number ) \qquad ( 1 )$$

and multiple interference is reinforced if a relationship of (2) is satisfied when n₁<n₂,

$$λ = \frac{2 d}{m} \times \sqrt{{n}_{1}^{2} - {sin}^{2} ϑ} ( m \text{:} natural number ) \qquad ( 2 )$$

For example, the index of refraction of air is 1, that of DLC (diamond-like carbon) is 2.42, that of Al₂O₃—TiC is 1.8, and that of alumina (Al₂O₃) is 1.76.

For explaining the formula (1), suppose that two incident light beams A and E impinge on the protective film from air at an incidence angle θ₁. After being refracted at an angle of refraction θ₂ at an interface surface B between air and the protective film, the light beam A is reflected at an interface surface C between the protective film and body part, and reaches an interface surface D between air and the protective film before being refracted into air again. On the other hand, the light beam E is reflected at the interface surface D between air and the protective film to interfere with the light beam A. If a foot from D perpendicular to BC is B₁ and an intersection of an extended line of BC and a vertical line from D is B₂, there is a relationship shown below for a path difference of two light beams of ABCDF and EDF

B₁C+CD=B₁C+CB₂=2d cos θ₂ (5)

and thus, an optical path difference 2n₁d cos θ₂ of the light beam A and light beam E has a relationship shown below:

2n₁d cos θ₂=2d\sqrt{n₁²−sin² θ₁} (6)

Here, the phase of reflected light at the interface surface D shifts by π from the relationship n₁>1. On the other hand, the phase of reflected light at the interface surface C does not shift when n₁>n₂, but shifts by π when n₁<n₂. Therefore, from the formula (4) and the phase of reflected light, multiple interference is caused when n₁>n₂ if the relationship of the formula (1) is satisfied, and multiple interference is caused when n₁<n₂ if the relationship of the formula (2) is satisfied. Using the interference of light described above, the position of the markers 27/28 can definitely be recognized. In this case, reflected light is measured by the angle of −θ.

Particularly when the incidence angle is 0° and n₁>n₂, if a relationship

$$λ = \frac{4 {n}_{1} d}{2 m + 1} ( m \text{:} natural number ) \qquad ( 3 )$$

is satisfied, multiple interference is caused and, when n₁<n₂, if a relationship

$$λ = \frac{2 {n}_{1} d}{m} ( m \text{:} natural number ) \qquad ( 4 )$$

is satisfied, multiple interference is caused and reinforced. In such cases, a light source part of incident light and a measuring part of reflected light can be provided in the same part and thus, the need to align the light source part of incident light and the measuring part of reflected light is eliminated so that the marker position can easily and definitely be recognized.

Conditions for reflected light to mutually reinforce by multiple interference in the markers are mainly described above. However, conversely by setting conditions for reflected light to mutually weaken by multiple interference in the markers, the markers can be recognized.

[Method of Manufacturing a Head Suspension Assembly]

Next, a method of manufacturing the head suspension assembly 8 by mounting the head slider 10 in the first embodiment or the second embodiment on the suspension 9 will be described.

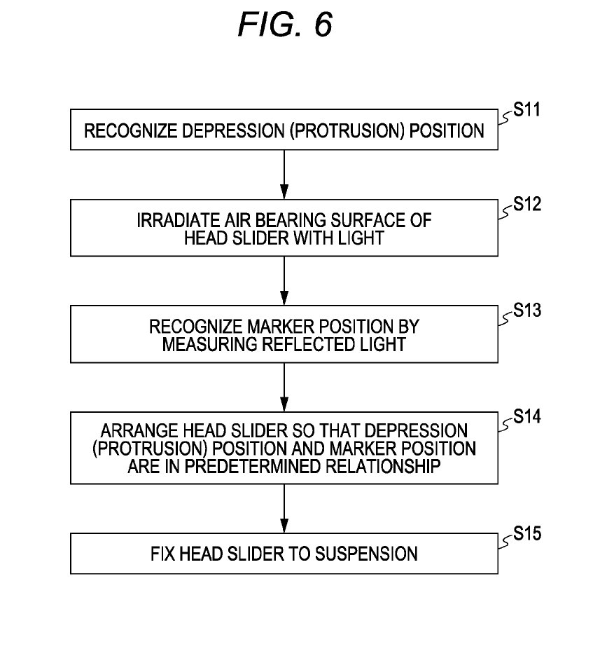

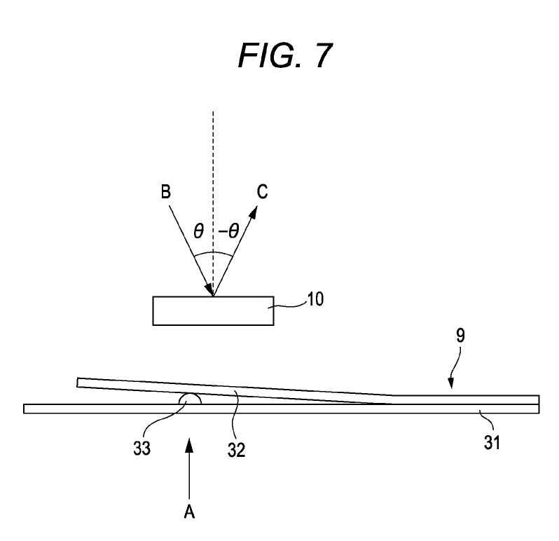

FIG. 6 is a flow chart of a method of manufacturing the head suspension assembly 8 according to the present invention. FIG. 7 is an explanatory view illustrating a method of mounting the head slider 10 on a tip side of the suspension 9. The suspension 9 includes a load beam 31 and a flexure 32 whose one end is fixed to the load beam 31. The flexure 32 is in contact with a dimple 33 on the load beam 31. The dimple 33 on the load beam 31 is formed by press working. Therefore. when viewed from a drawing A direction, a depression is formed. The position of the dimple 33 can be recognized by recognizing the position of the depression formed on the opposite surface of the dimple 33 (S11).

On the other hand, light of the wavelength (λ) is irradiated from a B direction on the air bearing surface of the head slider 10 at an incidence angle (θ) so that, for example, the condition of the formula (1) is satisfied (S12). At this time, the relationship of the index of refraction n₁ of the protective film of the head slider 10 and the index of refraction n₂ of the body part is n₁>n₂. The marker position of the head slider 10 is correctly recognized from the air bearing surface side by measuring reflected light reinforced by markers through multiple interference by the angle of −θ from a C direction (S13). The head slider 10 is arranged over the flexure 32 so that an air bearing surface pattern is arranged at a predetermined position with respect to a protrusion position (S14). In this state, the head slider 10 is fixed to the flexure 32 (S15). An adhesive or solder can be used to fix the head slider 10.

Compared with an error of machine work such as cutting and polishing, a position error with respect to an air bearing surface pattern of markers to be formed is extremely small and thus, even if the air bearing surface pattern is shifted with respect to an external shape of the head slider, the air bearing surface pattern and the protrusion position can be positioned to be in a predetermined position relationship with precision. Therefore, the center of gravity of load and that of buoyancy can be arranged in a predetermined position relationship to obtain stable buoyancy during operation. If the relationship of the index of refraction n₁ of the protective film of the head slider 10 and the index of refraction n₂ of the body part is n₁<n₂, light of the wavelength (λ) will be irradiated at the incidence angle (θ) so that the relationship of the formula (3) is satisfied.

According to a head slider in the present invention, an air bearing surface pattern of the head slider can be recognized with precision. Also, according to a method of manufacturing a head slider and a head suspension assembly in the present invention, the head slider can be mounted at a predetermined position of a suspension with high precision. Further, according to a head suspension assembly using a head slider in the present invention and a head suspension assembly manufactured by a method of manufacturing the head suspension assembly in the present invention, stable buoyancy can be obtained.

The order in which the embodiments have been described does not indicate superiority and inferiority of one embodiment over another. Although the embodiments of the present inventions have been described in detail, it should be understood that the various changes, substitutions, and alterations could be made hereto without departing from the spirit and scope of the invention.

What is claimed is:

1. A method of manufacturing a head suspension assembly for mounting a head slider on a suspension, comprising the steps of:
irradiating light on a protective film and a marker of the head slider at an incidence angle θ;
acquiring position information of the marker of the head slider by measuring reflected light from the protective film and that of the marker;
mounting the head slider at a predetermined position of the suspension by using the difference of the intensity of reflected light from the protective film and that of the marker, wherein
the head slider has a device part for reading information from a medium or writing information to a medium, a body part to be a substrate for forming the device part, and a protective film and a marker formed on an air bearing surface opposite to the medium surface, and
when light is irradiated on the protective film and the marker, intensity of reflected light from the protective film and that from the marker are different.

2. The method of manufacturing a head suspension assembly according to claim 1, wherein
the protective film and the marker are made of an identical material and a thickness of the protective film and that of the marker are different, and
if the thickness of the marker is d, indexes of refraction of the protective film and the marker are n₁, the index of refraction of the body part is n₂, and n₁>n₂, the head slider is mounted at the predetermined position of the suspension using the position information of the marker obtained by shining light of a wavelength λ satisfying a relationship:
$$λ = \frac{4 d}{2 m - 1} \times \sqrt{{n}_{1}^{2} - {sin}^{2} ϑ} ( m \text{:} natural number )$$
at an incidence angle θ with respect to a direction perpendicular to the air bearing surface of the body part and measuring reflected light of the light by the angle of −θ with respect to the direction perpendicular to the air bearing surface of the body part.

3. The method of manufacturing a head suspension assembly according to claim 2, wherein
light of the wavelength λ whose incidence angle with respect to the direction perpendicular to the air bearing surface of the body part of the light is 0° C. and satisfying a relationship:
$$λ = \frac{4 {n}_{1} d}{2 m - 1} ( m \text{:} natural number )$$
is irradiated.

4. The method of manufacturing a head suspension assembly according to claim 1, wherein
the protective film and the marker are made of an identical material and a thickness of the protective film and that of the marker are different, and
if the thickness of the marker is d, indexes of refraction of the protective film and the marker are n₁, the index of refraction of the body part is n₂, and n₁<n₂, the head slider is mounted at the predetermined position of the suspension using the position information of the marker obtained by shining light of a wavelength λ satisfying a relationship:
$$λ = \frac{2 d}{m} \times \sqrt{{n}_{1}^{2} - {sin}^{2} ϑ} ( m \text{:} natural number )$$
at an incidence angle θ with respect to a direction perpendicular to the air bearing surface of the body part and measuring reflected light of the light by the angle of −θ with respect to the direction perpendicular to the air bearing surface of the body part.

5. The method of manufacturing a head suspension assembly according to claim 4, wherein
light of the wavelength λ whose incidence angle with respect to the direction perpendicular to the air bearing surface of the body part of the light is 0° C. and satisfying a relationship:
$$λ = \frac{2 {n}_{1} d}{m} ( m \text{:} natural number )$$
is irradiated.

6. A head slider comprising:
a device part for reading information from a medium or writing information to a medium;
a body part to be a substrate for forming the device part; and
a protective film and a marker formed on an air bearing surface opposite to a medium surface of the body part, wherein
the marker is lower than a front air bearing surface arranged on a leading end side of the air bearing surface of the body part.

7. The head slider according to claim 6, wherein
the protective film and the marker are made of an identical material and if a thickness of the marker is d, indexes of refraction of the protective film and the marker are n₁, the index of refraction of the body part is n₂, and n₁>n₂ and light of a wavelength λ is irradiated at an incidence angle θ with respect to a direction perpendicular to the air bearing surface of the body part, a relationship:
$$λ = \frac{4 d}{2 m - 1} \times \sqrt{{n}_{1}^{2} - {sin}^{2} ϑ} ( m \text{:} natural number )$$
is satisfied.

8. The head slider according to claim 6, wherein
the protective film and the marker are made of an identical material and if a thickness of the marker is d, indexes of refraction of the protective film and the marker are n₁, the index of refraction of the body part is n₂, and n₁<n₂ and light of a wavelength λ is irradiated at an incidence angle θ with respect to a direction perpendicular to the air bearing surface of the body part, a relationship:
$$λ = \frac{2 d}{m} \times \sqrt{{n}_{1}^{2} - {sin}^{2} ϑ} ( m \text{:} natural number )$$
is satisfied.
